(19) United States
(12) Patent Application Publication
(10) Pub. No.: US 2012/0032242 A1
(43) Pub. Date: Feb. 9, 2012

(54) SEMICONDUCTOR DEVICE AND MANUFACTURING METHOD THEREOF

(75) Inventor: Yasuyuki AOKI, Kanagawa (JP)

(73) Assignee: RENESAS ELECTRONICS CORPORATION, Kanagawa (JP)

(21) Appl. No.: 13/178,972

(22) Filed: Jul. 8, 2011

(30) Foreign Application Priority Data
Aug. 9, 2010 (JP) 2010-178950

(51) Int. Cl. H01L 27/108; H01L 21/02

(52) U.S. Cl. 257/296; 438/381; 257/E27.084; 257/E21.008

(57) ABSTRACT

A semiconductor device includes: a diffusion layer configuring a memory cell, and a diffusion layer configuring a dummy cell formed over the semiconductor substrate, interlayer insulating films formed over the semiconductor substrate, a cylinder layer insulating film including at least one concavity overlapping a diffusion layer and formed over an interlayer insulating film, a contact plug formed over one diffusion layer, a contact plug formed over another diffusion layer, a lower electrode formed over the side surfaces and bottom surface of the concavity and coupled to the diffusion layer by way of the contact plug, a dielectric material film formed over the lower electrode, over the cylinder layer insulating film and over the contact plug, and coupling by way of the contact plug to the diffusion layer, and an upper electrode formed over the inductive film material.

### CROSS-REFERENCE TO RELATED APPLICATIONS

The disclosure of Japanese Patent Application No. 2010-178950 filed on Aug. 9, 2010 including the specifications, drawings, and abstract is incorporated herein by reference in its entirety.

### BACKGROUND

The present invention relates to a semiconductor device and a manufacturing method for that semiconductor device.

Among semiconductor storage devices, the DRAM allows freely inputting and outputting information as needed. The DRAM device should preferably have stable operation. Stable operation requires increasing the capacitance in order to retain electrical charges.

One method for increasing the DRAM capacitance is for example forming the capacitor as a cylinder structure. Another method is reducing the film thickness of the inductive material in the capacitor. However, reducing the dielectric material film thickness might sometimes destroy the insulation in the dielectric material film due to static charges due to electrical charges on the plate electrode that comprises the capacitor during the process for manufacturing the semiconductor device.

A technology to resolve this problem is disclosed in Japanese Unexamined Patent Application Publication No. 2002-324851. The technology disclosed in the Japanese Unexamined Patent Application Publication No. 2002-324851 forms an insulation protection capacitor that is coupled to an insulation protection diffusion layer separate from the, capacitor that configures the memory cell. The technology disclosed here can prevent insulation breakdown in the dielectric material film by discharging the electrical charges that accumulated on the plate electrode into an insulation protection diffusion layer by way of an insulation protection capacitor.

### SUMMARY

Along with stable operation, the semiconductor device also must also make efficient use of the surface area. However the technology disclosed in Japanese Unexamined Patent Application Publication No. 2002-324851 requires a region on which to form the insulation protection diffusion layer and also an insulation protection capacitor. The technology in Japanese Unexamined Patent Application Publication No. 2002-324851 therefore does not make efficient use of the surface area within the semiconductor device.

According to one aspect of the present invention, a semiconductor device includes:

a memory cell, and

a dummy cell positioned adjacent to the memory cell, and further includes:

a semiconductor substrate,

a first diffusion layer configuring the memory cell formed over the semiconductor substrate,

a second diffusion layer configuring the dummy cell formed over the semiconductor substrate,

an interlayer insulating film including at least one concavity overlapping the first diffusion layer formed over the semiconductor substrate as seen from a flat view,

a first contact plug formed over the first diffusion layer,

a second contact plug formed over the second diffusion layer,

a lower electrode formed over the side surface and the bottom surface of the concavity, coupled to the first diffusion layer by way of the first contact plug,

a dielectric material film formed consecutively over the lower electrode, over the interlayer insulating film positioned on the periphery of the concavity, and over the second contact plug, and coupled with the second diffusion layer by way of the second contact plug, and

an upper electrode formed over the dielectric material film.

In the aspect of the present invention, the dielectric material film is coupled to the diffusion layer forming the dummy cell. Electrical charges accumulated on the upper electrode can therefore escape by way of the dielectric material film to the diffusion layer that forms the dummy cell. Destruction of the insulation in the dielectric material film that is prone to occur in the manufacturing process is therefore prevented by utilizing just a portion of the region forming the dummy cell, and without requiring formation of another diffusion layer. The semiconductor device of the present invention can therefore provide stable operation while efficiently utilizing the surface area within the semiconductor device.

According to another aspect of the present invention, a manufacturing method for a semiconductor device having a memory cell, and a dummy cell positioned adjacent to the memory cell, includes the steps of: forming a first diffusion layer to configure the memory cell, and forming a second diffusion layer to configure the dummy cell; forming an interlayer insulating film over the semiconductor substrate; forming a first lower contact plug passing through the interlayer insulating film and coupling to the first diffusion layer, and also forming a second lower contact plug passing through the interlayer insulating film and coupling to the second diffusion layer; forming a cylinder layer insulating film over the first lower contact plug, and over the second lower contact plug, over the interlayer insulating film; forming an upper contact plug passing through the cylinder layer insulating film, over the second lower contact plug; forming at least one concavity passing through the cylinder layer insulating film, in the cylinder layer insulating film to expose the first lower contact plug; forming a lower electrode over the side surface and the bottom surface of the concavity; forming a dielectric material film consecutively over the lower electrode, over the cylinder layer insulating film, and over the upper contact plug; and forming an upper electrode over the dielectric material film; all over the semiconductor substrate.

The present invention therefore renders a semiconductor device capable of stable operation along with efficient usage of the surface area within the semiconductor device.

### BRIEF DESCRIPTION OF THE DRAWINGS

FIG. 1 is a cross sectional view for showing the semiconductor device of a first embodiment;

FIG. 2 is a flat view showing the semiconductor device in FIG. 1;

FIG. 3 is a cross sectional view for showing the manufacturing method for the semiconductor device in FIG. 1;

FIG. 4 is a cross sectional view for showing the manufacturing method for the semiconductor device in FIG. 1;

FIG. 5 is a cross sectional view for showing the manufacturing method for the semiconductor device in FIG. 1;

FIG. 6 is a cross sectional view for showing the manufacturing method for the semiconductor device in FIG. 1;

FIG. 7 is a cross sectional view for showing the manufacturing method for the semiconductor device in FIG. 1;

FIG. 8 is a cross sectional view for showing the semiconductor device of the second embodiment;

FIG. 9 is a flat view for showing the semiconductor device in FIG. 8; and

FIG. 10 is a cross sectional view showing the semiconductor device uses as a comparative example.

### DETAILED DESCRIPTION

The embodiment of the present invention is described next while referring to the drawings. In all the drawings, the same structural components are assigned the same reference numerals, and redundant descriptions omitted where applicable.

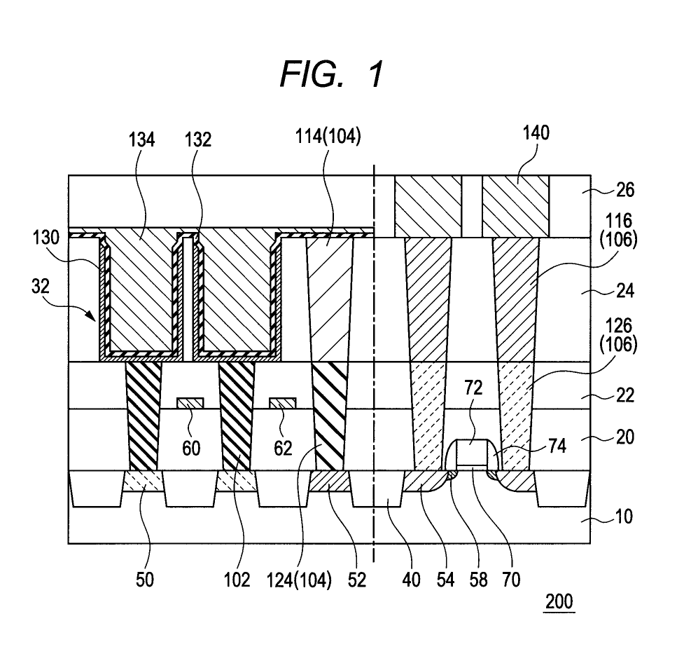

FIG. 1 is a cross sectional view for showing the semiconductor device 200 of the first embodiment. A semiconductor device 200 contains a DRAM region including a memory cell and a dummy cell. The dummy cell is provided in order to stabilize the DRAM operation and is not utilized as a memory. The semiconductor device 200 is comprised of a semiconductor substrate 10, a diffusion layer 50, a diffusion layer 52, an interlayer insulating films 20, 22, a cylinder layer insulating film 24, the contact plugs 102, 104, a lower electrode 130, a dielectric material film 132, and an upper electrode 134.

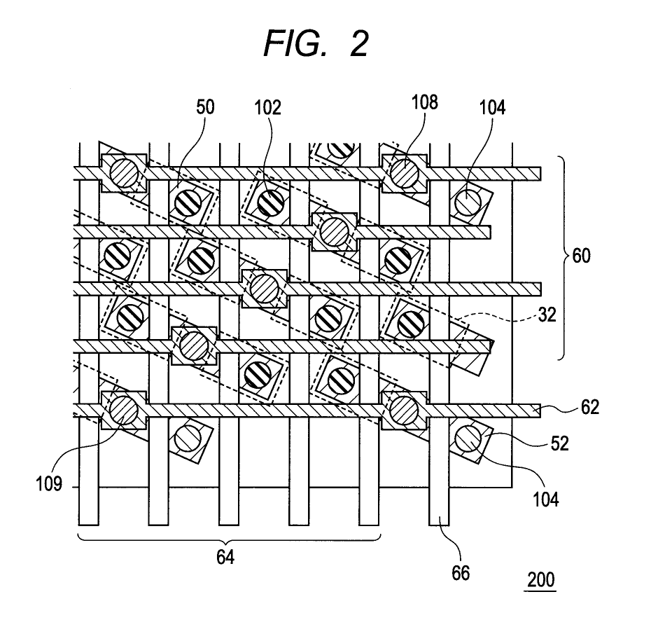

The composition of the semiconductor device 200 is described next in detail while referring to FIG. 1 and FIG. 2. Here, FIG. 2 is a flat view showing the semiconductor device in FIG. 1. The semiconductor device 200 contains a device isolation region 40 as shown in FIG. 1. The diffusion layers 50, 52 are formed over the semiconductor substrate 10 and are mutually isolated by the device isolation region 40. The diffusion layer 50 comprises the transistor source/drain regions for the memory cell. The diffusion layer 52 comprises the dummy cell.

An interlayer insulating film 20 is formed over the semiconductor substrate 10. This interlayer insulating film 20 is comprised for example of SiO₂ (silicon dioxide). An interlayer insulating film 22 is also formed over the interlayer insulating film 20. This interlayer insulating film 22 is comprised for example of SiO2 (silicon dioxide). The contact plug 102 is formed over the diffusion layer 50. A lower contact plug 124 to comprise the contact plug 104 is formed over the diffusion layer 52. The contact plug 102 and the lower contact plug 124 pass through the interlayer insulating film 20, 22. The contact plug 102 and the lower contact plug 124 are comprised for example from W (tungsten).

A cylinder layer insulating film 24 is formed over the interlayer insulating film 22. A plurality of concavities 32 are formed within the cylinder layer insulating film 24. At least one among these concavities is positioned so as to overlap the diffusion layer 50. The concavities 32 pass through the cylinder layer insulating film 24, and expose the contact plug 102 on the bottom surface. An upper contact plug 114 that comprises the contact plug 104 is formed over the lower contact plug 124. The upper contact plug 114 passes through the cylinder layer insulating film 24. The upper contact plug 114 is comprised for example of W (tungsten).

A lower electrode 130 is formed over the side surface and the bottom surface of the concavity 32 that was formed over the cylinder layer insulating film 24. The lower electrode 130 is coupled by way of the contact plug 102 to the diffusion layer 50. The lower electrode 130 is comprised of material such as TiN (titanium nitride), having a higher resistance than the material of the contact plug 104. A dielectric material film 132 is formed over the lower electrode 130, over the cylinder layer insulating film 24, and over the contact plug 104. The dielectric material film 132 is coupled by way of the contact plug 104 to the diffusion layer 52. The dielectric material film 132 is comprised of material having a high dielectric constant such as Ta₂O₅ (tantalum oxide) or ZrO₂ (zirconium oxide). An upper electrode 134 is formed over the dielectric material film 132. The upper electrode 134 is comprised for example of TiN. A wiring layer insulating film 26 is formed over the cylinder layer insulating film 24, over the upper electrode 134, and over the contact plug 106. This wiring layer insulating film 26 is comprised of a dielectric film possessing a low dielectric constant such as organic silicon oxide film.

The semiconductor device 200 as shown in FIG. 1 contains a bit line 60 and a dummy bit line 62. The bit line 60 and the dummy bit line 62 are positioned below the lower electrode 130, and formed over the interlayer insulating film 20. Moreover, the bit line 60 is coupled to the diffusion layer 50 by way of the bit contact plug 108 as shown in FIG. 2. The dummy bit line 62 is coupled by way of the dummy bit contact plug 109 to the diffusion layer 52. Further, the semiconductor device 200 as shown in FIG. 2 includes a word line 64, and a dummy word line 66. The dummy cell is coupled to the dummy bit line 62, or the dummy word line 66.

The semiconductor device 200 further includes a logic region containing a logic circuit section. The semiconductor device 200 is comprised of transistor, a contact plug 106, and a metallic wire 140 that comprise the logic circuit section. The transistor is comprised of a gate dielectric film 70, a gate electrode 72, a sidewall 74, a diffusion layer 54, and an extension region 58.

A diffusion layer 54 is formed in the semiconductor substrate 10, and is isolated from the diffusion layers 50, 52 by the device isolation region 40. The diffusion layer 54 comprises the source/drain regions. A lower contact plug 126 that comprises the contact plug 106 is formed over the diffusion layer 54. The lower contact plug 126 passes through the interlayer insulating films 20, 22. The lower contact plug 126 is for example comprised of W (tungsten). An upper contact plug 116 that comprises the contact plug 106 is formed over the lower contact plug 126. The upper contact plug 116 passes through the cylinder layer insulating film 24. The upper contact plug 116 is for example comprised of W (tungsten). The metallic wire 140 is formed over the contact plug 106. The metallic wire 140 is comprised of Cu (copper).

As shown in FIG. 1, an extension region 58 is formed over the semiconductor substrate 10, extending to the inner side from the source/drain region comprised of the diffusion layer 54. A gate dielectric film 70 is formed between the source/drain regions over the semiconductor substrate 10. A gate electrode 72 is also formed over the gate dielectric film 70. A sidewall 74 is formed on the sidewall of the gate electrode 72 and the gate dielectric film 70.

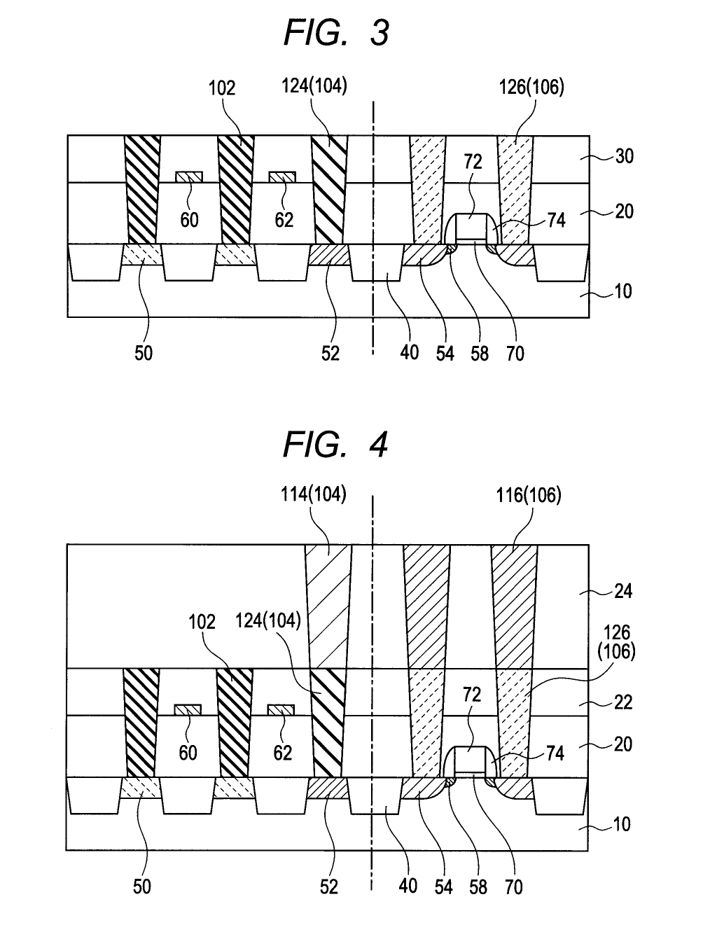

The method for manufacturing the semiconductor device 200 is described next while referring to FIG. 1 and FIG. 3 through FIG. 7. Here, FIG. 3 through FIG. 7 are cross sectional views showing the method for manufacturing the semiconductor device 200 in FIG. 1. A device isolation region 40 is first of all formed over the semiconductor substrate 10 as shown in FIG. 3. Next, the gate dielectric film 70, and the gate electrode 72 are formed over the semiconductor substrate 10. Impurity ions are then injected into the semiconductor substrate 10 using the device insulation region 40 and the gate electrode 72 as a mask, to form the extension region 58. A dielectric (insulating) film is also deposited over the semiconductor substrate 10, and this deposit is then etched back to form the sidewall 74. Impurity ions are then injected into the semiconductor substrate 10 utilizing the device insulation region 40, the gate electrode 72, and the sidewall 74, as a mask to form the diffusion layers 50, 52, and 54.

The interlayer insulating film 20 is next formed over the semiconductor substrate 10, and the gate electrode 72. A bit contact plug 108 (Refer to FIG. 2) is then embedded into the interlayer insulating film 20 so as to position it over the diffusion layer 50. A dummy bit contact plug 109 (Refer to FIG. 2) is then embedded into the interlayer insulating film 20 at the same time so as to position it over the diffusion layer 52. Then, along with forming a bit line 60 over the interlayer insulating film 20, and over the bit contact plug 108; a dummy bit line 62 is formed over the interlayer insulating film 20, and the dummy bit contact plug 109.

An interlayer insulating film 22 is formed over the interlayer insulating film 20, over the bit line 60, and over the dummy bit line 62. The contact plug 102 is then embedded into the interlayer insulating films 20, 22 so as to position it over the diffusion layer 50. The lower contact plug 124 is embedded into the interlayer insulating films 20, 22 at the same time so as to position it over the diffusion layer 52. Further, the lower contact plug 126 is embedded into the interlayer insulating films 20, 22 at the same time so as to position it over the diffusion layer 54.

Next, as shown in FIG. 4, the cylinder layer insulating film 24 is formed over the interlayer insulating film 22, over the contact plug 102, the lower contact plug 124, and over the lower contact plug 126. The upper contact plug 114 is then embedded into the cylinder layer insulating film 24 so as to position it over the lower contact plug 124. The upper contact plug 116 is embedded into the cylinder layer insulating film 24 at the same time so as to position it over the lower contact plug 126.

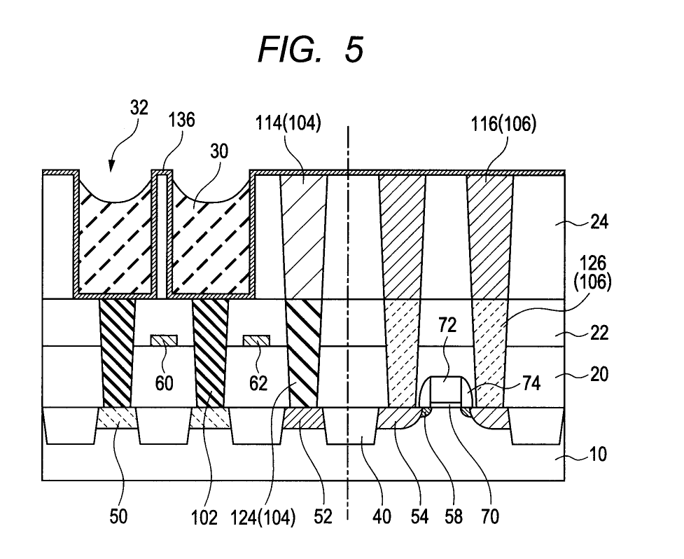

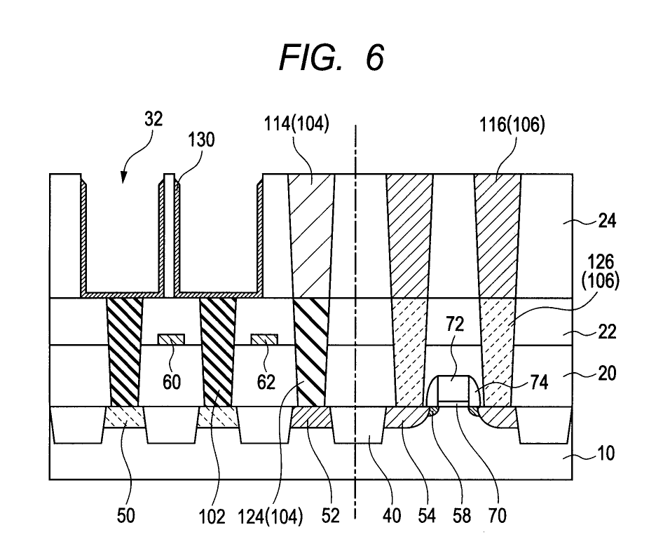

A concavity 32 is next formed in the cylinder layer insulating film 24 as shown in FIG. 5. The concavity 32 passes through the cylinder layer insulating film 24, and exposes the contact plug 102 on the bottom surface. The conductive film 136 that comprises the lower electrode 130 is then formed over the side surfaces and the bottom surface of the concavity 32, and over the cylinder layer insulating film 24. A resist (solution) is then coated over the conductive film 136 and the surface exposed to light. This lithography process leaves the resist 30 remaining within the concavity 32. The conductive film 136 is then dry etched using the resist 30 as a mask. The resist 30 is then removed. The lower electrode 130 is formed in this way over the bottom surface and side surfaces of the concavity 32 as shown in FIG. 6.

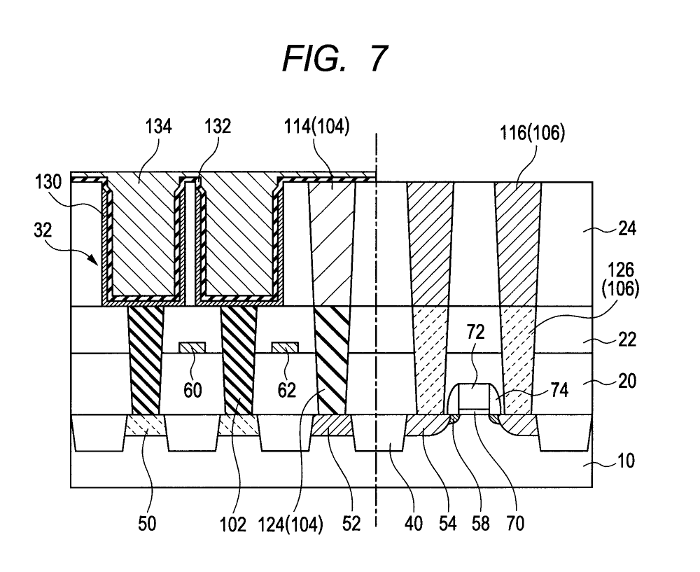

Next, the dielectric material film 132 and the upper electrode 134 are formed over the lower electrode 130, over the cylinder layer insulating film 24, and over the contact plug 104 and selectively stripped away as shown in FIG. 7. The wiring layer insulating film 26 is formed over the cylinder layer insulating film 24, over the upper electrode 134, and over the contact plug 104, and planarizing performed by CMP (chemical mechanical polishing). The metallic wire 140 is formed afterwards to achieve the semiconductor device 200 as shown in FIG. 1.

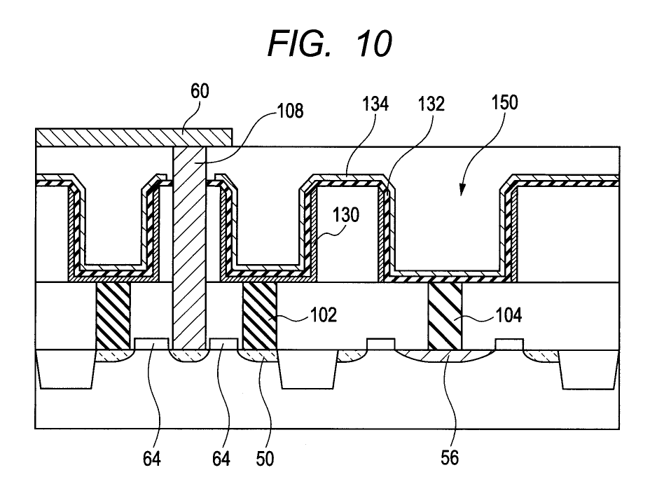

The effect rendered by the embodiment is described next. FIG. 10 is a cross sectional view showing the semiconductor device of the comparative example. A diffusion layer 56 that does not configure the memory cell is formed over the semiconductor substrate 10. An insulation protected capacitor 150 is formed over the diffusion layer 56 so as to couple the dielectric material film 132 to the diffusion layer 56 by way of the contact plug 104. Electrical charges that accumulated on the upper electrode 134 during the manufacturing process are therefore discharged to the diffusion layer 56 after passing though the insulation protected capacitor 150, and the contact plug 104. Breakdown of the insulation in the dielectric material film 132 is prevented in this way. However the improvement in surface area usage efficiency in the semiconductor device of the comparative example cannot be assessed.

In the present embodiment however, the dielectric material film 132 is coupled to the diffusion layer 52 that comprises a dummy cell. Breakdown of the insulation in the dielectric material film 132 can therefore be prevented by utilizing a portion of the region that configures the dummy cell, and without having to form a diffusion layer 56 and insulation protected capacitor 150. The semiconductor device of the present invention can therefore provide stable operation with more efficient usage of the surface area within the semiconductor device.

Also in this embodiment, the material that comprises the contact plug 104 has a resistance value lower than the material configuring the lower electrode 130. The electrical charge that accumulates on the upper electrode 134 therefore passes through the contact plug 104 and easily discharges into the diffusion layer 52. Breakdown of the insulation in the dielectric material film can therefore be prevented to an even greater degree.

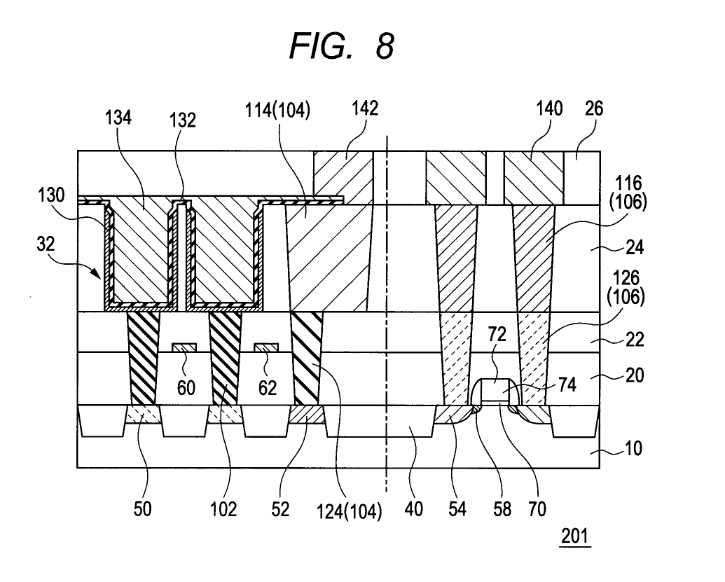

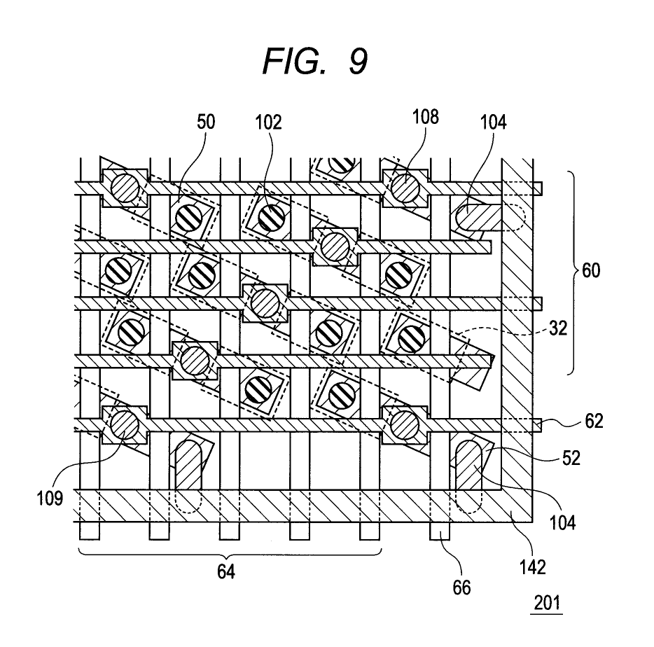

FIG. 8 is a cross sectional view for showing the semiconductor device 201 of the second embodiment and corresponds to the device of the first embodiment shown in FIG. 1. FIG. 9 is a flat view showing the semiconductor device 201 shown in FIG. 8, and corresponds to the first embodiment shown in FIG. 2.

In the semiconductor device 201 as shown in FIG. 8, the contact plug 104 is exposed over the cylinder layer insulating film 24. The conductive film 142 is then formed over the upper electrode 134, and over the contact plug 104. The upper electrode 134 is therefore coupled by way of the conductive film 142 and the contact plug 104 to the diffusion layer 52.

The effect of the present embodiment is described next. This embodiment can provide the same effects as in the first embodiment. The upper electrode 134 also couples to the diffusion layer 52 by way of the conductive film 142 and the contact plug 104. In other words, the conductive material forms the only path from the upper electrode 134 to the diffusion layer 52. So compared to the case where discharging by way of dielectric material film, in this embodiment the electrical charges accumulated on the upper electrode are swiftly discharged into the diffusion layer that comprises the dummy cell.

The embodiment of the present invention was described while referring to the drawings however these are examples of the present invention and all manner of adaptations and variations may be employed.

What is claimed is:

1. A semiconductor device comprising:
a memory cell;
a dummy cell positioned adjacent to the memory cell;
a semiconductor substrate;
a first diffusion layer comprising the memory cell formed over the semiconductor substrate;
a second diffusion layer comprising the dummy cell formed over the semiconductor substrate;
an interlayer insulating film including at least one concavity overlapping the first diffusion layer formed over the semiconductor substrate as seen from a flat view;
a first contact plug formed over the first diffusion layer;
a second contact plug formed over the second diffusion layer;
a lower electrode formed over the side surface and the bottom surface of the concavity, and coupled to the first diffusion layer by way of the first contact plug;
a dielectric material film consecutively formed over the lower electrode, over the interlayer insulating film positioned on the periphery of the concavity, and over the second contact plug, and coupled to the second diffusion layer by way of the second contact plug;
an upper electrode formed over the dielectric material film.

2. The semiconductor device according to claim 1,
wherein the interlayer insulating film includes a plurality of concavities, and
wherein the dielectric material film is consecutively formed over the lower electrodes positioned at the respective concavities, and over the interlayer insulating film positioned between the concavities.

3. The semiconductor device according to claim 1,
wherein the resistance value of the material of the second contact plug is lower than the resistance value of the material of the lower electrode.

4. The semiconductor device according to claim 1,
wherein the lower electrode is made of titanium nitride (TiN) and the second contact plug is made of tungsten (W).

5. The semiconductor device according to claim 1, further comprising:
bit line formed within the interlayer insulating film so as to be positioned lower than the lower electrode.

6. The semiconductor device according to claim 1, further including a logic circuit section, comprising:
a third diffusion layer including the logic circuit section formed on the semiconductor substrate;
a third contact plug formed on the third diffusion layer, and
a metallic wire formed over the interlayer insulating film, and coupling to the third diffusion layer by way of the third contact plug.

7. The semiconductor device according to claim 1,
wherein the second contact plug is exposed over the interlayer insulating film on the outer side of the region where the upper electrode is formed,
wherein the semiconductor device further comprises a conductive film formed consecutively over the upper electrode, and over the second contact plug, and
wherein the upper electrode is coupled by way of the conductive film and the second contact plug to the second diffusion layer.

8. A manufacturing method for the semiconductor device including a memory cell; and a dummy cell positioned adjacent to the memory cell, the method comprising:
forming a first diffusion layer comprising the memory cell, and also forming a second diffusion layer comprising the dummy cell;
forming an interlayer insulating film over the semiconductor substrate;
forming a first lower contact plug passing through the interlayer insulating film and coupling to the first diffusion layer, and also forming a second lower contact plug passing through the interlayer insulating film and coupling to the second diffusion layer;
forming a cylinder layer insulating film over the interlayer insulating film, over the first lower contact plug, and over the second lower contact plug;
forming an upper contact plug passing through the cylinder layer insulating film, over the second lower contact plug;
forming at least one concavity that passes through the cylinder layer insulating film, within the cylinder layer insulating film, to expose the first lower contact plug;
forming a lower electrode over the side surfaces and the bottom surface of the concavity;
forming a dielectric material film consecutively over the lower electrode, over the cylinder layer insulating film, and over the upper contact plug; and
forming an upper electrode over the dielectric material film; all on the semiconductor substrate.
